(19) United States
(12) Patent Application Publication
(10) Pub. No.: US 2009/0277669 A1
(43) Pub. Date: Nov. 12, 2009

(54) FLEXIBLE PRINTED CIRCUITBOARD WITH ANTI-SOLDER CRACK STRUCTURE

(75) Inventors: Yu-Chieh KUAN, Taichung County (TW); Chin-Wen LO, Taichung City (TW)

Correspondence Address: WPAT, PC, 7225 BEVERLY ST., ANNANDALE, VA, 22003, US

(73) Assignee: WINTEK CORPORATION, TAICHUNG (TW)

(21) Appl. No.: 12/437,319

(22) Filed: May 7, 2009

(30) Foreign Application Priority Data
May 9, 2008 (TW) 097117092

(51) Int. Cl. H05K 1/02

(52) U.S. Cl. 174/254

(57) ABSTRACT

A flexible printed circuitboards (FPC) with anti-solder crack structure, adapted for a plurality of circuit components to mount thereon, is disclosed, which comprises: a vacant area, being a region of high aspect ratio formed on the FPC at a location where the FPC is more likely to be bended and is enclosed by the plural circuit components; a layout area, being a region formed on the FPC at a location beyond that of the vacant area so as to be provided for the plural circuit components to mount thereon. By the formation of the vacant area on the FPC at its stress concentration region when it is bended by an external force, stresses in solder bumps bonding the plural circuit components with the FPC can be prevented from happening so that the reliability of circuit component against solder crack is improved.

### FIELD OF THE INVENTION

The present invention relates to a flexible print circuitboard (FPC) with anti-solder crack structure, and more particularly, to a FPC designed with a layout area located at a region of the FPC beyond where it is more likely to be bended and thus is the potential stress concentration area of the FPC.

### BACKGROUND OF THE INVENTION

Generally, a flexible printed circuitboard (FPC) is an epoxy resin plate which has curtailed circuits densely formed on a surface thereof so as to be used for connecting the respective circuit components to each other and thus for establishing signal transmission therebetween. On a common FPC, there are usually at least one circuit component being mounted on the FPC which is used for control signal input and output and the mounting of the circuit component on the FPC for establishing electrically conduction therebetween is achieved by the use of a solder paste or a conductive adhesive. Nevertheless, since such FPC is designed to be bended before it can be fitted in a specific electric device, the generating of stresses on the FPC at the regions where it is bended is inevitable. Therefore, if there are circuit components 61 being mounted on the FPC at its stress concentration areas 60, as shown in FIG. 1, those circuit components are more than likely to break and fall off from the FPC by the stresses.

In the mean time, as the designs for all kinds of consumer electronic products are becoming thinner, lighter and smaller, there can be less space provided therein for fitting a FPC so that the small a FPC is the more popular it will be. However, when the FPC is becoming smaller, there can be less layout space available on the FPC so that the design principle of current FPC is to cram in as many circuit components on the limited space by a manner as easy as possible. However, such design principle usually produces a FPC that is vulnerable to solder cracking problem when it is subject to an external impact during transportation or assembly.

### SUMMARY OF THE INVENTION

In view of the disadvantages of prior art, the object of the present invention is to provide an anti-solder crack structure for FPC, which is achieved by forming at least one layout area on a FPC, each provided for a circuit component to electrically connected thereat, while enabling each layout area to be structured in a manner that the longitudinal side of the corresponding circuit component mounted thereon is orientated parallel to the longitudinal side of a region of the FPC where it is designed to be bended, by which those circuit components mounted on the FPC can be prevented from breaking and falling off from the FPC by the stresses occurred in the bended region of the same.

To achieve the above object, the present invention provides a flexible printed circuitboard (FPC) with anti-solder crack structure, adapted for a plurality of circuit components to mount thereon, which comprises: a vacant area, being a region of high aspect ratio formed on the FPC at a location where is the narrowest part of the FPC; and a layout area, being a region formed on the FPC at a location beyond that of the vacant area so as to be provided for the plural circuit components to mount thereon.

In an exemplary embodiment, the present invention provides another flexible printed circuitboard (FPC) with anti-solder crack structure, adapted for a plurality of circuit components to mount thereon, which comprises: a vacant area, being a region of high aspect ratio formed on the FPC along a diagonal line connecting two corners of the FPC whose diagonal distance is the smallest on the FPC; and a layout area, being a region formed on the FPC at a location beyond that of the vacant area so as to be provided for the plural circuit components to mount thereon.

Yet, in another exemplary embodiment, the present invention provides another flexible printed circuitboard (FPC) with anti-solder crack structure, adapted for a plurality of circuit components to mount thereon, which comprises: a main portion; and an extension portion, extruding extendedly from a connection edge of the main portion which is formed on a side of the main portion; wherein the width of the connection edge is smaller than the portion of the side of the main portion that it is beyond the connection edge; and the connection edge is designed to be a vacant area, being a region of high aspect that is enclosed by the plural circuit components.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 is a schematic diagram showing a conventional flexible printed circuitboard.

FIG. 2 is a schematic diagram showing a flexible printed circuitboard with anti-solder crack structure according to a first embodiment of the invention.

FIG. 3 is a schematic diagram showing a flexible printed circuitboard with anti-solder crack structure according to a second embodiment of the invention.

FIG. 4 is a schematic diagram showing a flexible printed circuitboard with anti-solder crack structure according to a third embodiment of the invention.

FIG. 5 is a schematic diagram showing how the circuit components can be disposed on a layout area while such layout area is disposed crossing a vacant area.

FIG. 6 is a schematic diagram showing how a layout area is structured for enabling the longitudinal side of the corresponding circuit components mounted thereon to be orientated parallel to the longitudinal side of a vacant area of the FPC.

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

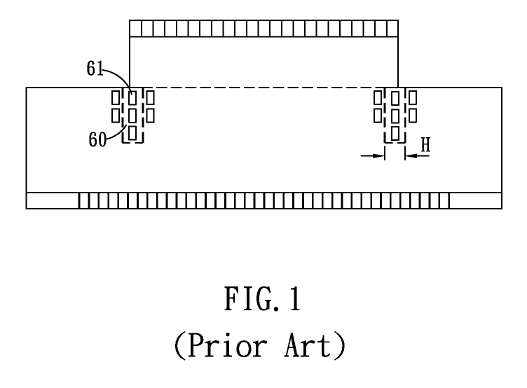

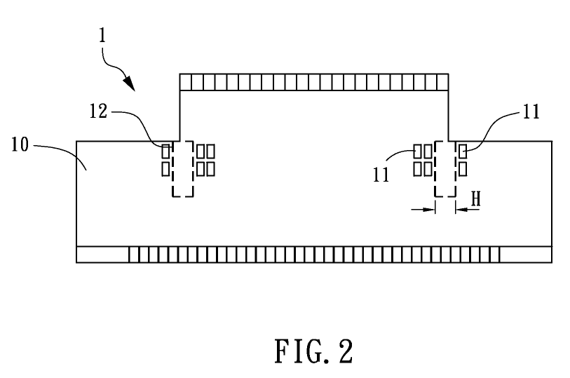

Please refer to FIG. 2, which is a schematic diagram showing a flexible printed circuitboard with anti-solder crack structure according to a first embodiment of the invention. In FIG. 1, the flexible printed circuitboard (FPC) with anti-solder crack structure 1 is adapted for a plurality of circuit components 11 to mount thereon, in which each of the plural circuit components 11 is soldered on the FPC 1. Moreover, the FPC 1 is comprised of: a vacant area 12, being a region of high aspect ratio formed on the surface of the FPC 1 at a location where the FPC 1 is more likely to be bended and is enclosed by the plural circuit components 11; and a layout area 10, being a region formed on the FPC 1 at a location beyond that of the vacant area 12 so as to be provided for the plural circuit components 11 to mount thereon.

In this first embodiment, the vacant area 12 is formed at the narrowest part of the FPC 1 so that when the FPC 1 is subjected to a sideway external force, the FPC will be bended at the vacant area 12 as it is the narrowest.

The width H of the vacant area 12 can be any value and can be varied according to the thickness of the FPC 1. As shown in FIG. 2, the plural circuit components 11 are disposed outside the longitudinal sides of the vacant area 12 by that the vacant area 12 is separated from the layout area 10.

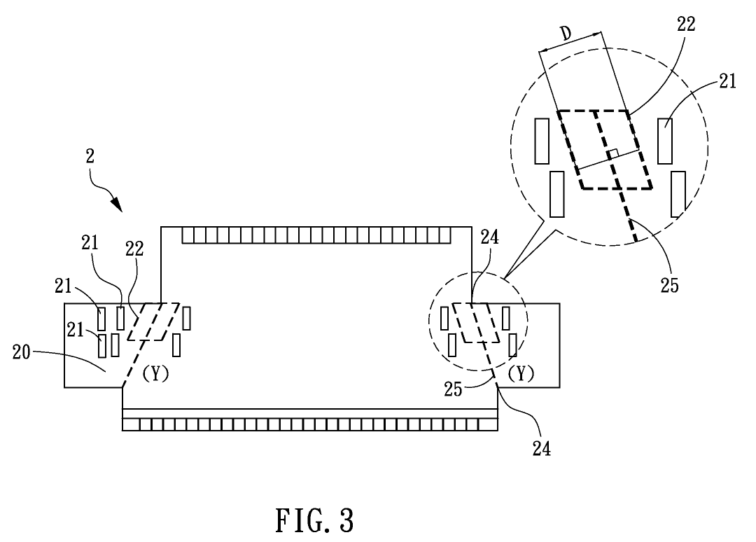

Please refer to FIG. 3, which is a schematic diagram showing a flexible printed circuitboard with anti-solder crack structure according to a second embodiment of the invention. In FIG. 3, the flexible printed circuitboard (FPC) with anti-solder crack structure 2 is adapted for a plurality of circuit components 21 to mount thereon, in which each of the plural circuit components 21 is soldered on the FPC 2. Moreover, the FPC 2 is comprised of: a vacant area 22, being a region of high aspect ratio formed on the surface of the FPC 2 at a location enclosed by the plural circuit components 21; and a layout area 20, being a region formed on the FPC 2 at a location beyond that of the vacant area 22 so as to be provided for the plural circuit components 21 to mount thereon. It is noted that the vacant area 22 is basically a slander region enclosed by the plural circuit components 21.

In this second embodiment, the vacant area 22 is a region of high aspect ratio formed on the FPC 2 along a diagonal line 25 connecting two corners 24 of the FPC 2 whose diagonal distance is the smallest on the FPC 2. It is noted that the width D of the vacant area 22 can be any value and can be varied according to the thickness of the FPC 1, whereas he width D of the vacant area 22 is defined as the length of a line normal to the diagonal line 25. As shown in FIG. 3, the plural circuit components 21 are disposed outside the longitudinal sides of the vacant area 22. Thereby, as the vacant area 22 is extending diagonally, the distance between the two circuit components disposed at the two opposite side of the vacant area 22 is larger than that measured in the first embodiment.

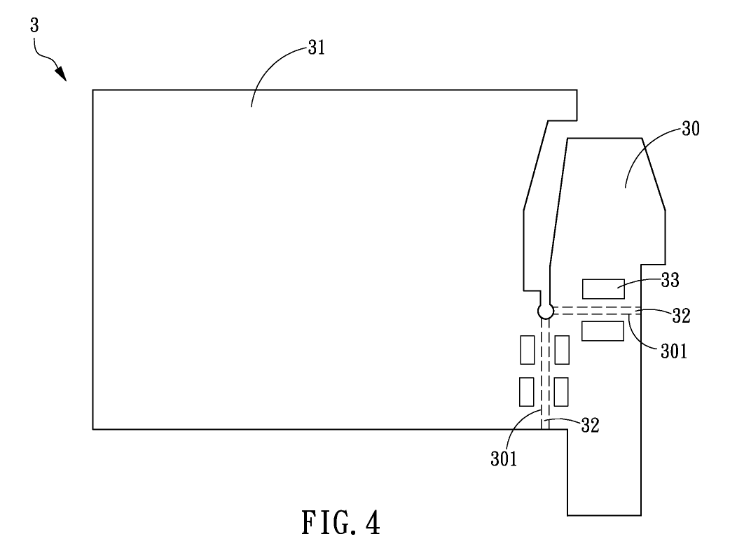

Please refer to FIG. 4, which is a schematic diagram showing a flexible printed circuitboard with anti-solder crack structure according to a third embodiment of the invention. In FIG. 4, the flexible printed circuitboard (FPC) with anti-solder crack structure 3, being adapted for a plurality of circuit components 33 to mount thereon, is comprised of: a main portion 31; and an extension portion 30. The extension portion 30, whose area is smaller than that of the main portion 31, is extruding extendedly from a connection edge 301 of the main portion 31 which is formed on a side of the main portion 31, and the width of the connection edge 301 is smaller than the portion of the side of the main portion 31 that it is beyond the connection edge 301.

It is note that there is a vacant area 32 being formed directly along the connection edge 301 that it is a region of high aspect that is enclosed by the plural circuit components 33. That is, the vacant area 32 is a slander region enclosed by the plural circuit components 33. Moreover, each of the plural circuit components 33 is soldered on the FPC 3. In addition, the area of the FPC 3 that is not the vacant area 32 is defined as a layout area, which is a region formed on the FPC at a location beyond that of the vacant area 32 so as to be provided for the plural circuit components 33 to mount thereon.

In this third embodiment, the vacant area 32 is formed at the narrowest portion of the FPC 3, or when the FPC is configured with the extension portion 30 which is basically an extension extruding from a side of the main portion 31, the vacant area 32 is the portion of the FPC formed next to the connection edge 301 joining the extension portion 30 and the main portion 31.

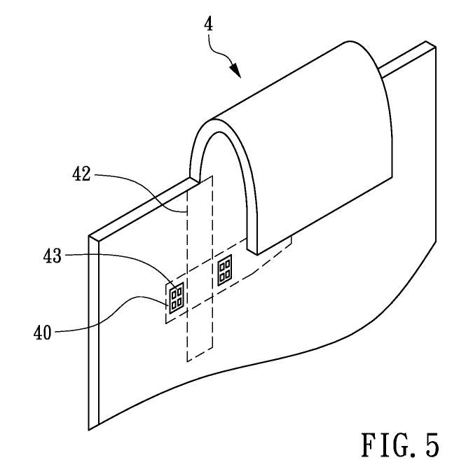

Please refer to FIG. 5, which is a schematic diagram showing how the circuit components can be disposed on a layout area while such layout area is disposed crossing a vacant area. In FIG. 5, the FPC 4 comprises at least a layout area 40, which is provided for at least a circuit component 43 to mount thereon, where there are two such circuit components 43 shown in FIG. 5. Since the arrangement of the layout area 43 is restricted by the limited space of the FPC 4, the layout area 40 is disposed crossing a vacant area 42. Therefore, in order to prevent the circuit components 43 form being subjecting to a stress, the two circuit components 43 are disposed in the layout area 40 at locations where are beyond the vacant area 42.

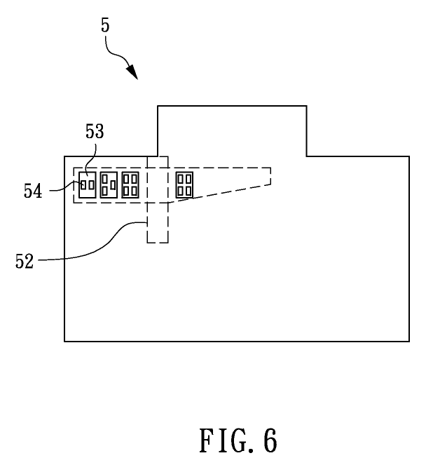

Please refer to FIG. 6, which is a schematic diagram showing how a layout area is so structured for enabling the longitudinal side of the corresponding circuit components mounted thereon to be orientated parallel to the longitudinal side of a vacant area of the FPC. In FIG. 6, there are several carrying layers 54 being formed on a surface of the FPC 5, each of which is provided for a circuit component 53 to mount thereon. It is noted that the disposition of the carrying layer 54 is also the true for the FPCs in the aforesaid three embodiments. In addition, a carrying layer set 54 is defined as a group consisting of at least one carrying layer 54. Each carrying layer 54 is made of a conductive material, which can be copper as that used in the aforesaid three embodiments. The circuit components 53 is soldered on the FPC 5 in a manner that the longitudinal side of each of the plural circuit components 53 is orientated parallel to the longitudinal side of the vacant area 52, and also the longitudinal side of each of the carrying layer 54 is orientated parallel to the longitudinal side of the vacant area 52.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A flexible printed circuitboard (FPC) with anti-solder crack structure, adapted for a plurality of circuit components to mount thereon, comprising:
a vacant area, being a region of high aspect ratio formed on the FPC at a location where is the narrowest part of the FPC; and
a layout area, being a region formed on the FPC at a location beyond that of the vacant area so as to be provided for the plural circuit components to mount thereon.

2. The flexible printed circuitboard of claim 1, wherein the plural circuit components are mounted on the layout area for enabling the longitudinal side of each of the plural circuit components to be orientated parallel to the longitudinal side of the vacant area.

3. The flexible printed circuitboard of claim 1, wherein each of the plural circuit components is spaced from the flexible printed circuitboard by a carrying layer.

4. The flexible printed circuitboard of claim 3, wherein the carrying layer is made of copper.

5. A flexible printed circuitboard (FPC) with anti-solder crack structure, adapted for a plurality of circuit components to mount thereon, comprising:
a vacant area, being a region of high aspect ratio formed on the FPC along a diagonal line connecting two corners of the FPC whose diagonal distance is the smallest on the FPC; and
a layout area, being a region formed on the FPC at a location beyond that of the vacant area so as to be provided for the plural circuit components to mount thereon.

6. The flexible printed circuitboard of claim 5, wherein the plural circuit components are mounted on the layout area for enabling the longitudinal side of each of the plural circuit components to be orientated parallel to the longitudinal side of the vacant area.

7. The flexible printed circuitboard of claim 5, wherein each of the plural circuit components is spaced from the flexible printed circuitboard by a carrying layer.

8. The flexible printed circuitboard of claim 5, wherein the carrying layer is made of copper.

9. A flexible printed circuitboard (FPC) with anti-solder crack structure, adapted for a plurality of circuit components to mount thereon, comprising:
a main portion; and
an extension portion, extruding extendedly from a connection edge of the main portion which is formed on a side of the main portion;
wherein the width of the connection edge is smaller than the portion of the side of the main portion that it is beyond the connection edge; and the connection edge is designed to be a vacant area, being a region of high aspect that is enclosed by the plural circuit components.

10. The flexible printed circuitboard of claim 9, further comprising:
a layout area, being a region formed on the FPC at a location beyond that of the vacant area so as to be provided for the plural circuit components to mount thereon.

11. The flexible printed circuitboard of claim 9, wherein the plural circuit components are mounted on the layout area for enabling the longitudinal side of each of the plural circuit components to be orientated parallel to the longitudinal side of the vacant area.

12. The flexible printed circuitboard of claim 9, wherein each of the plural circuit components is spaced from the flexible printed circuitboard by a carrying layer.

13. The flexible printed circuitboard of claim 12, wherein the carrying layer is made of copper.
